(19) United States
(12) Patent Application Publication
(10) Pub. No.: US 2026/0344207 A1
(43) Pub. Date: Oct. 29, 2026

(54) DISPLAY APPARATUS

(71) Applicant: LG Display Co., Ltd., Seoul (KR)

(72) Inventors: Choong-Keun YOO, Paju-si (KR); Binn KIM, Paju-si (KR)

(73) Assignee: LG Display Co., Ltd., Seoul (KR)

(21) Appl. No.: 19/576,560

(22) Filed: Mar. 24, 2026

(30) Foreign Application Priority Data
Apr. 29, 2025 (KR) 10-2025-0055984

(51) Int. Cl. H10K 59/126; H10K 59/131; G09G 3/3233

(52) U.S. Cl. CPC H10K 59/126; H10K 59/131; G09G 3/3233; G09G 2300/0426; G09G 2300/0452; G09G 2300/0842; G09G 2320/045; G09G 2330/02

(57) ABSTRACT

A display apparatus includes a substrate having a plurality of sub-pixels and a light emitting device disposed in each subpixel, the light emitting device including a first electrode, a light emitting layer, and a second electrode. A fence is disposed along an outer periphery of each sub-pixel, and an end of the fence is formed in an undercut shape. A shielding electrode is disposed on the fence and is integrally formed with the first electrode while being electrically disconnected from the first electrode by the undercut shape. A voltage is applied to the shielding electrode so that an electric field in a boundary region between adjacent sub-pixels is suppressed, thereby reducing unintended light emission and color mixing between neighboring sub-pixels.

### CROSS-REFERENCE TO RELATED APPLICATIONS

This application claims priority to Korean Patent Application No. 10-2025-0055984, filed in the Republic of Korea on April 29, 2025, the entire contents of which is hereby expressly incorporated by reference into the present application.

### BACKGROUND

### TECHNICAL FIELD

The present disclosure relates to a display apparatus, and more particularly, to the display apparatus having improved light emission characteristics.

### DESCRIPTION OF THE RELATED ART

Recently, with the development of multimedia, the importance of display apparatuses is increasing. In response to this, flat panel display apparatuses, such as a liquid crystal display apparatus, a plasma display apparatus, and an organic light emitting display apparatus, are being commercialized. Among these display apparatuses, the organic light emitting display apparatus is currently widely used because of its high response speed, high luminance, and wide viewing angle.

To manufacture a high resolution display apparatus, the gap between sub-pixels typically need to be minimized or reduced. However, in this case, as the gap between adjacent sub-pixels decreases, a lateral leakage current is more likely to be generated between adjacent sub-pixels. This side leakage current may cause unwanted light emission in pixels, which is an important cause of defect in the display apparatus.

### BRIEF SUMMARY

The present disclosure addresses a limitation of high resolution emissive displays in which reduced spacing between sub pixels allows lateral leakage current through the light emitting layer, generating electric fields at pixel boundaries that cause unintended emission, color mixing, mura, and device degradation. Conventional pixel defining layers provide only physical separation and do not suppress the boundary electric field. The structure instead places a shielding electrode on the fence surrounding each sub pixel and biases it to the same potential as the second electrode so that the electric field at the boundary is substantially eliminated and light emission does not occur even when leakage current is present.

The shielding electrode is formed during the same deposition as the pixel electrode and is electrically separated by an undercut profile of the fence, removing the need for an additional mask and enabling self aligned fabrication. The undercut also interrupts continuity of the light emitting layer, providing both reduction of lateral current flow and suppression of the boundary electric field. In certain embodiments the shielding potential is supplied through reflective layers or related structures so that additional wiring is not required and compatibility with wavelength tuned micro-cavity stacks for different colors is maintained.

The structure therefore replaces a passive pixel bank with an electrically biased boundary region that controls the electric field at pixel edges. This improves color purity, reduces crosstalk and power consumption, and enhances device lifetime while simplifying manufacturing through fewer masking steps and automatic alignment of electrodes.

Various embodiments of the present disclosure provide a display apparatus capable of preventing mixing of light of a specific color output from adjacent pixels.

In order to achieve the object, the display apparatus according one aspect of the present disclosure comprises a substrate including a plurality of sub-pixels, a light emitting device disposed in each of the sub-pixels, the light emitting device including a first electrode, a light emitting layer, and a second electrode, a fence disposed along the outer periphery of the sub-pixel, an end of the fence being formed in an undercut shape, and a shielding electrode on the fence, the shielding electrode being integrally formed with the first electrode, wherein first electrode and the shielding electrode are electrically disconnected by the undercut shape, and wherein a voltage is applied to the shielding electrode.

The shielding electrode and the second electrode may have the same potential.

The substrate may be made of at least one of a wafer, a plastic material, and glass

A thin film transistor is disposed in each of the sub-pixels, a passivation layer is disposed over the thin film transistor, and the thin film transistor is electrically connected to the first electrode through a first contact hole formed in the passivation layer.

A reflective layer is disposed over the passivation layer and a planarization layer is formed thereon. The shielding electrode is electrically connected to the reflective layer through a second contact hole formed in the planarization layer and a third contact hole formed in the fence.

A groove may be formed in a region corresponding to the undercut shape of the planarization layer.

An external power voltage is supplied to the shielding electrode through the reflective layer and the power supply voltage may be a low potential voltage.

The display apparatus according to another aspect of the present disclosure comprises a substrate including a plurality of R (Red), G (Green), B (Blue) sub-pixels, a light emitting device disposed in each of the R, G , B sub-pixels, the light emitting device including a first electrode, a light emitting layer, and a second electrode, a fence disposed along the outer periphery of the plurality of the R, G, B sub-pixel, an end of the fence being formed in an undercut shape, a shielding electrode on the fence, the shielding electrode being integrally formed with the first electrode, wherein first electrode and the shielding electrode are electrically disconnected by the undercut shape, and wherein a voltage is applied to the shielding electrode.

The thin film transistor is disposed in each of the plurality of R, G, B sub-pixels, a passivation layer is disposed over the thin film transistor, and a first reflective layer is disposed on the passivation layer in the R sub-pixel. A first planarization layer is disposed on the passivation layer on which the first reflective layer is disposed and a second reflective layer is disposed on the first planarization layer in the G sub-pixel. A second planarization layer is disposed on the first planarization layer on which the second reflective layer is disposed and a third reflective layer is disposed on the second planarization layer in the B sub-pixel.

A first reflective layer and a second reflective layer may be respectively disposed on the passivation layer in the R sub-pixel and the G sub-pixel, and a first planarization layer may be disposed in the R sub-pixel and a portion of the G sub-pixel on the passivation layer on which the first reflective layer is disposed. A second planarization layer may be disposed in the plurality of the R, G, B sub-pixels to cover the first planarization layer and the second reflective layer and a third reflective layer may be disposed on the second planarization layer in the B sub-pixel.

The light emitting devices of the R and G sub-pixels may be disposed on the second planarization layer, and the light emitting device of the B sub-pixel may be disposed on the third reflective layer so that the first electrode of the B sub-pixel is directly contacted with the third reflective layer.

The shielding electrode of the R sub-pixel may be electrically connected to the first reflective layer through a first contact hole formed in the first planarization layer, the second planarization layer, and the fence to apply voltage to the shielding electrode, and the shielding electrode of the G sub-pixel may be electrically connected to the second reflective layer through a second contact hole formed in the second planarization layer and the fence to apply the voltage to the shielding electrode

A voltage line is disposed on the first planarization layer in B sub-pixel, and the shielding electrode of the B sub-pixel may be electrically connected to the voltage line through a third contact hole formed in the second planarization layer and the fence to apply the voltage to the shielding electrode.

The first reflective layer and the second reflective layer may be respectively extended to a partial area of the B sub-pixel so that the shielding electrode of the B sub-pixel may be electrically connected to the first reflective layer and the second reflective layer to apply the voltage to the shielding electrode.

### BRIEF DESCRIPTION OF THE SEVERAL VIEWS OF THE DRAWINGS

FIG. 1 is a schematic block diagram of a display apparatus according to the present disclosure.

FIG. 2 is the schematic block diagram of a sub pixel according to the present disclosure.

FIG. 3 is a circuit diagram conceptually illustrating the sub pixel of an organic light emitting display apparatus according to the present disclosure.

FIG. 4 is a cross-sectional view illustrating a structure of the display apparatus according to a first embodiment of the present disclosure.

FIG. 5 is an enlarged cross-sectional view of area A of FIG. 4.

FIG. 6A is the view schematically illustrating the display apparatus having a structure in which a shielding electrode is not disposed.

FIG. 6B is the view schematically illustrating the display apparatus according to the present disclosure in which the shielding electrode is disposed.

FIGS. 7A to 7F are the cross-sectional views illustrating a method of manufacturing the display apparatus according to a first embodiment of the present disclosure.

FIG. 8 is the cross-sectional view illustrating the structure of the display apparatus according to a second embodiment of the present disclosure.

FIG. 9 is the cross-sectional view illustrating the structure of the display apparatus according to a third embodiment of the present disclosure.

FIG. 10s the cross-sectional view illustrating the structure of the display apparatus according to a fourth embodiment of the present disclosure.

FIG. 11 is the cross-sectional view illustrating the structure of the display apparatus according to a fifth embodiment of the present disclosure.

### DETAILED DESCRIPTION

Advantages and features of the present disclosure and methods for achieving them will be made clear from embodiments described in detail below with reference to the accompanying drawings. The present disclosure may, however, be implemented in many different forms and should not be construed as being limited to the embodiments set forth herein, and the embodiments are provided such that this disclosure will be thorough and complete and will fully convey the scope of the present disclosure to those skilled in the art to which the present disclosure pertains.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

The same reference numerals refer to the same components throughout this disclosure. Further, in the following description of the present disclosure, when a detailed description of a known related art is determined to unnecessarily obscure the gist of the present disclosure, the detailed description thereof will be omitted herein. When terms such as “including,” “having,” “comprising,” and the like mentioned in this disclosure are used, other parts may be added unless the term “only” is used herein. When a component is expressed as being singular, being plural is included unless otherwise specified.

In analyzing a component, an error range is interpreted as being included even when there is no explicit description.

In describing a positional relationship, for example, when a positional relationship of two parts is described as being “on,” “above,” “below,” “next to,” or the like, unless “immediately” or “directly” is not used, one or more other parts may be located between the two parts.

In describing a temporal relationship, for example, when a temporal predecessor relationship is described as being “after,” “subsequent,” “next to,” “prior to,” or the like, unless “immediately” or “directly” is not used, cases that are not continuous may also be included.

Although the terms first, second, and the like are used to describe various components, these components are not substantially limited by these terms. These terms are used only to distinguish one component from another component. Therefore, a first component described below may substantially be a second component within the technical spirit of the present disclosure.

In describing the components of the disclosure, terms such as first, second, A, B, (a), (b), etc., may be used. These terms are only for distinguishing the elements from other elements, and the essence, order, or number of the elements are not limited by the terms. When it is described that a component is “connected” “coupled” or “connected” to another component, the component may be directly connected or connected to the other component, but indirectly without specifically stated It should be understood that other components may be “interposed” between each component that is connected or can be connected.

To further elaborate, as used herein, the term "connected" is intended to have the broadest possible meaning. Specifically, the phrase "A is connected to B" encompasses both a direct connection—where no intervening components or elements are present—and an indirect connection, where one or more intermediate components or elements exist between A and B. In other words, "A is connected to B" includes both direct physical or electrical coupling and indirect coupling through one or more intervening components. Unless explicitly stated otherwise, these terms do not require direct physical or electrical contact. The terms "coupled" and "in contact" should be interpreted in the same manner.

As used herein, the term “apparatus” may include a display apparatus such as a liquid crystal module (LCM) including a display panel and a driving unit for driving the display panel, and an organic light emitting display module (OLED module). Further, the term “apparatus” may further include a notebook computer, a television, a computer monitor, a vehicle electric apparatus including an apparatus for a vehicle or other type of vehicle, and a set electronic apparatus or a set apparatus such as a mobile electronic apparatus of a smart phone or an electronic pad, etc., which are a finished product (complete product or final product) including LCM and OLED module.

Accordingly, the apparatus in the disclosure may include the display apparatus itself such as the LCM, the OLED module, etc., and the application product including the LCM, the OLED module, or the like, or the set apparatus, which is the apparatus for end users.

Hereinafter, the present disclosure will be described in detail with reference to the accompanying drawings.

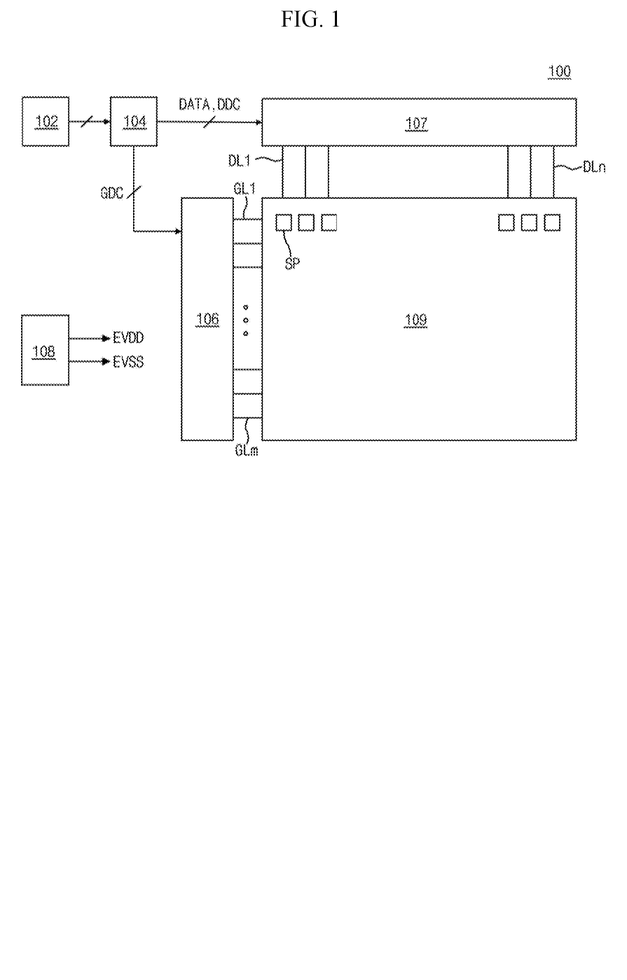

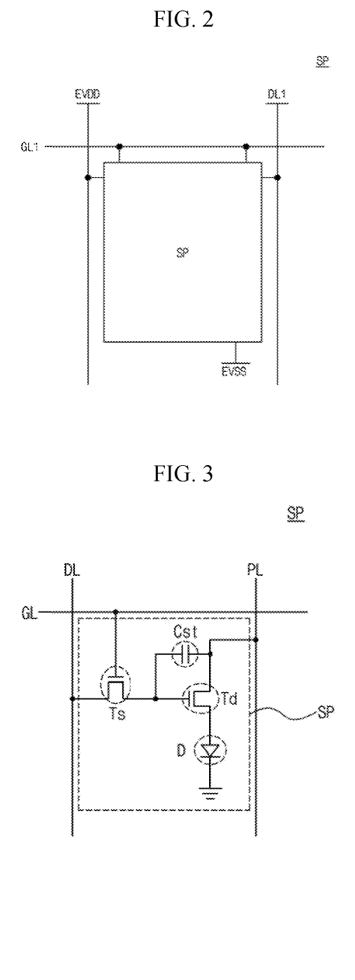

FIG. 1 is the schematic block diagram and FIG. 2 is the schematic block diagram of the sub-pixel of the organic light emitting display apparatus according to the present disclosure.

As shown in FIG. 1, the organic light emitting display apparatus 100 includes an image processing unit 102, a timing controlling unit 104, a gate driving unit 106, a data driving unit 107, a power supplying unit 108, and a display panel 109.

The image processing unit 102 outputs an image data supplied from outside and a driving signal for driving various devices. For example, the driving signal from the image processing unit 102 can include a data enable signal, a vertical synchronizing signal, a horizontal synchronizing signal, and a clock signal.

The image data and the driving signal are supplied to the timing controlling unit 104 from the image processing unit 102. The timing controlling unit 104 writes and outputs gate timing controlling signal GDC for controlling the driving timing of the gate driving unit 106 and data timing controlling signal DDC for controlling the driving timing of the data driving unit 107 based on the driving signal from the image processing unit 102.

The gate driving unit 106 outputs the scan signal to the display panel 109 in response to the gate timing control signal GDC supplied from the timing controlling unit 104. The gate driving unit 106 outputs the scan signal through a plurality of gate lines GL1 to GLm. In this case, the gate driving unit 106 may be formed in the form of an integrated circuit (IC), but is not limited thereto.

The data driving unit 107 outputs the data voltage to the display panel 109 in response to the data timing control signal DDC input from the timing controlling unit 104. The data driving unit 107 samples and latches the digital data signal DATA supplied from the timing controlling unit 104 to convert it into the analog data voltage based on the gamma voltage. The data driving unit 107 outputs the data voltage through the plurality of data lines DL1 to DLn. In this case, the data driving unit 107 may be mounted on the upper surface of the display panel 109 in the form of an integrated circuit (IC), but is limited thereto.

The power supplying unit 108 outputs a high potential voltage VDD and a low potential voltage VSS, etc., to supply these to the display panel 109. The high potential voltage VDD is supplied to the display panel 109 through the first power line EVDD and the low potential voltage VSS is supplied to the display panel 109 through the second power line EVSS. In this time, the voltage from the power supplying unit 108 are applied to the data driving unit 107 or the gate driving unit 106 to drive thereto.

The display panel 109 displays the image based on the data voltage from the data driving unit 108, the scan signal from the gage driving unit 106, and the power from the power supplying unit 108.

The display panel PAN includes a plurality of sub-pixels SP to display the image. The sub-pixel SP can include Red sub-pixel, Green sub-pixel, and Blue sub-pixel. Further, the sub-pixel SP can include White sub-pixel, the Red sub-pixel, the Green sub-pixel, and the Blue sub-pixel. The White sub-pixel, the Red sub-pixel, the Green sub-pixel, and the Blue sub-pixel may be formed in the same area or may be formed in different areas.

As shown in FIG. 2, one sub-pixel SP may be connected to the gate line GL1, the data line DL1, the first power line EVDD, and the second power line EVSS. In the sub-pixel SP, the number of transistors and capacitors as well as the driving method are determined according to the configuration of the pixel circuit.

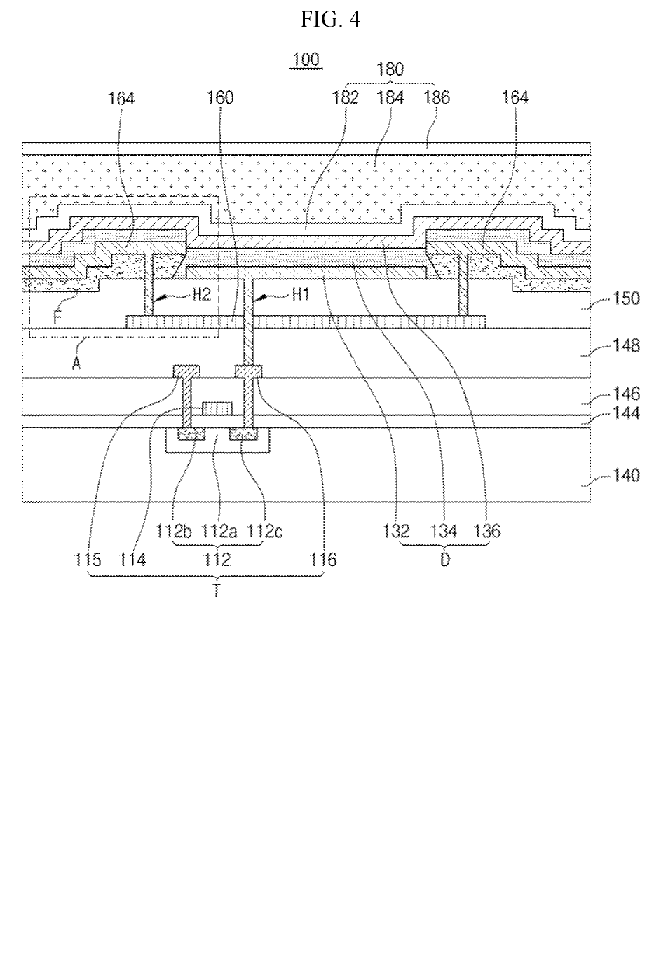

FIG. 3 is the circuit diagram illustrating the sub-pixel SP of the organic light emitting display apparatus 100 according to the present disclosure.

As shown in FIG. 3, the organic light emitting display apparatus 100 according to the present disclosure includes the gate line GL, the data line DL, and the power line PL crossing each other for defining the sub-pixel SP. A switching thin film transistor Ts, a driving thin film transistor DT, a storage capacitor Cst, and an organic light emitting device D are disposed in the sub-pixel SP.

The switching thin film transistor Ts is connected to the gate line GL and the data line DL, and the driving thin film transistor Td and the storage capacitor Cst are connected between the switching thin film transistor Ts and the power line PL. The organic light emitting device D is connected to the driving thin film transistor Td.

In the organic light emitting display apparatus having this structure, when the switching thin film transistor Ts is turned on according to the gate signal applied to the gate line GL, the data signal applied to the data line DL is applied to the gate electrode of the driving thin film transistor Td and one electrode of the storage capacitor Cst through the switching thin film transistor Ts.

The driving thin film transistor Td is turned on according to the data signal applied to the gate electrode. As a result, the current proportional to the data signal is supplied to the organic light emitting device D from the power line PL through the driving thin film transistor Td and then the organic light emitting device D emits light with a luminance proportional to the current flowing through the driving thin film transistor Td.

At this time, the storage capacitor Cst is charged with the voltage proportional to the data signal to keep the voltage of the gate electrode of the driving thin film transistor Td constant for one frame.

In the figure, only two thin film transistors Td and Ts and one capacitor Cst are provided, but the present disclosure is not limited thereto. Three or more thin film transistors and two or more capacitors may be provided in the present disclosure.

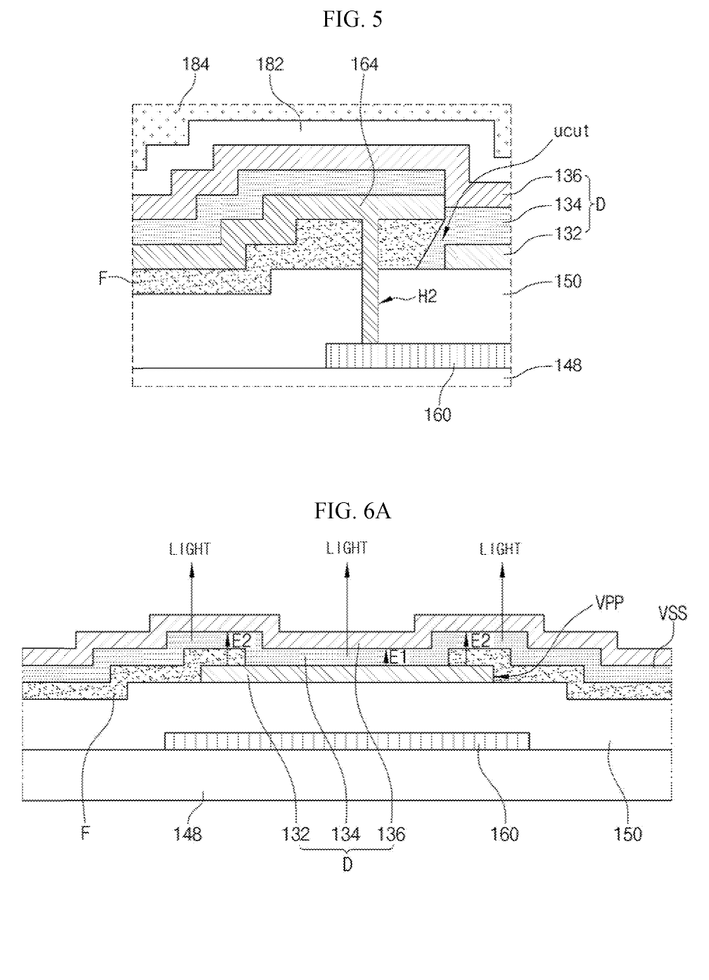

FIG. 4 is the cross-sectional view illustrating the structure of the display apparatus 100 according to a first embodiment of the present disclosure. The display apparatus 100 includes a plurality of R, G, and B sub-pixels, but for convenience of description, only one sub-pixel is shown in the drawing.

As shown in FIG. 4, in the organic light emitting display apparatus 100 according to the first embodiment of the present disclosure, a transistor T is disposed on the wafer substrate 140.

The wafer substrate 140 may be a single crystal silicon wafer formed by growing single crystal silicon (Si), but is not limited thereto and may be the wafer formed of various semiconductor materials.

The thin film transistor includes an active region 112 disposed inside the wafer substrate 140, a gate insulating layer 144 covering the active region 112, a gate electrode 114 on the gate insulating layer 144, an interlayer insulating layer 146 covering the gate electrode 114, and a source electrode 115 and a drain electrode 116 on the interlayer insulating layer 146.

The active region 112 may be formed inside the wafer substrate 140. The active region 112 of the wafer substrate 140 may include a central channel region 112athat is not doped with impurities, a source region 112b and drain region 112c that are doped with impurities on both sides of the channel region 112a.

The gate insulating layer 144 may be composed of a single layer or multiple layers made of an inorganic material such as SiOx or SiNx, but is not limited thereto.

The gate electrode 114 may be made of a metal. For example, the gate electrode 114 may be formed of the single layer or multi layers made of one or alloys of molybdenum (Mo), aluminum (Al), chromium (Cr), gold (Au), titanium (Ti), nickel (Ni), neodymium (Nd), and copper (Cu), but is not limited thereto.

The interlayer insulating layer 146 may be made of the organic material such as photo-acryl, or the interlayer insulating layer 146 may formed of the single layer or the multiple layers made of the inorganic material such as SiOx or SiNx, but is not limited thereto. Further, the interlayer insulating layer 146 may be formed of the multi layers of the organic material layer and the inorganic material layer, but is not limited thereto.

The source electrode 115 and the drain electrode 116 are formed of the single layer or multi layers made of one or alloys of molybdenum (Mo), aluminum (Al), chromium (Cr), gold (Au), titanium (Ti), nickel (Ni), neodymium (Nd), and copper (Cu), but is not limited thereto. The source electrode 115 and the drain electrode 116 may be respectively contacted to the source region 112b and the drain region 112c of the active region 112 through contact holes formed in the gate insulating layer 144 and the interlayer insulating layer 146.

Although not shown in the drawings, a buffer layer may be disposed between the wafer substrate 140 and the gate insulating layer 144. The buffer layer 142 enhances adhering force between the wafer substrate 140 and the layers thereon. Further, the buffer layer 142 may block various types of defects, such as alkali components flowing out from the substrate 140. In addition, the buffer layer 142 may delay diffusion of moisture or oxygen penetrating into the substrate 140. The buffer layer 142 may be a single layer made of silicon oxide (SiOx) or silicon nitride (SiNx), or multi-layers thereof. When the buffer layer 142 is made of multiple layers, SiOx and SiNx may be alternately formed.

A passivation layer 148 is formed on the wafer substrate 110 on which the transistor T is disposed. The passivation layer 148 may be formed of the organic material such as photo acrylic, but is not limited thereto and may also be formed of a plurality of layers including of the inorganic layer and the organic layer.

The reflective layer 160 is formed on the passivation layer 148. The reflective layer 160 may be made of the metal having good reflectivity, such as Ag or Al, but is not limited thereto. In this case, the reflective layer 160 is floated so that no signal is applied thereto.

A planarization layer 150 is disposed on the passivation layer on which the reflective layer 160 is disposed. The planarization layer 150 may be formed of the organic material such as photo acrylic. But it is not limited thereto. The planarization layer 150 may include a plurality of layers including the inorganic layer and the organic layer. Further, the planarization layer 150 may be formed of the same material as the passivation layer 148, but may be formed of a different material.

A light emitting device D is disposed in each sub-pixel SP1 and SP2 on the planarization layer 150. The light emitting device D includes a first electrode 132, a light emitting layer 134, and a second electrode 136.

The first electrode 132 is disposed on the planarization layer 150 and electrically connected to the drain electrode 116 of the thin film transistor through the first contact hole H1 formed in the planarization layer 150.

Although the first contact hole H1 penetrates the reflective layer 160 in the drawing, this is due to the characteristics of the cross-sectional view. Since the first contact hole H1 is formed in the planarization layer 150 of the area where the reflective layer 160 is not formed, the reflective layer 160 and the first electrode 132 are electrically insulated from each other.

The first electrode 132 may be made of the half-transparent conductive material that transmits light. For example, the first electrode 132 may be made of at least one or more of the alloys such as LiF/Al, CsF/Al, Mg:Ag, Ca/Ag, Ca:Ag, LiF/Mg:Ag, LiF/Ca/Ag, or LiF/Ca:Ag. Further, the first electrode 132 may be made of the transparent metal oxide layer such as an indium tin oxide (ITO) or an indium zinc oxide (IZO). Since the display apparatus 100 according to the present disclosure is a top emission type, the first electrode 132 may be made of the transparent metal. However, in the present disclosure, the light emitting efficiency of the light emitting device D may be improved by providing the reflective layer 160 at the lower portion of the light emitting device D to reflect the light output from the light emitting device D upward.

In addition, the reflective layer 160 improves the light extraction efficiency of the light emitting device D by the micro-cavity. The micro-cavity multi-reflects light between two reflective layers to resonate the light, thereby improving the light emission efficiency of the light emitting device D.

Since the length of the micro-cavity is dependent upon the wavelength of light and the length of the micro-cavity varies according to the thickness of the planarization layer 150 above the reflective layer 160, t the thickness of the planarization layer 150 in the present disclosure is different for sub-pixels. For example, since the wavelength of the R sub-pixel is the longest and the wavelength of the B sub-pixel is the shortest, the thickness of the planarization layer 150 of the R sub-pixel is the largest and the thickness of the B-sub-pixel is the smallest.

Further, the planarization layer 150 may be formed of different numbers of layers for each of R, G, and B sub-pixels. For example, the planarization layer 150 of the R sub-pixel may include three layers, the planarization layer 150 of the G sub-pixel may include two layers, and the planarization layer 150 of the B sub-pixel may include a single layer.

In addition, the planarization layer 150 may formed of the single layer. In this case, the reflective layer 160 may be disposed below the planarization layer 150 in R and G sub-pixels that output light having a relatively long wavelength, and the reflective layer 160 may be disposed above the planarization layer 150 in B sub-pixels that output light having a relatively short wavelength, thereby maximizing a micro-cavity effect. At this time, the first electrode 132 of the light emitting device D may be directly disposed on the reflective layer 160 in the B sub-pixel where the reflective layer 160 is disposed on the planarization layer 150.

A fence F is formed at the boundary between the sub-pixels on the planarization layer 150. The fence F is formed to surround the sub-pixel to define the sub-pixel. Specifically, the fence F is overlapped with a portion of the edge region of the first electrode 132 to partition each sub-pixel, so that the light of the specific color output from the sub-pixel is not mixed to the light of the different color output from the adjacent sub-pixel.

The fence F may be made of the inorganic material such as SiOx or SiNx, but is not limited thereto.

The light emitting layer 134 is disposed in the sub-pixel surrounded by a fence F. The light emitting layer 134 may be formed in R, G, and B pixels and include an R-light emitting layer for emitting red light, a G-light emitting layer for emitting green light, and a B-light emitting layer for emitting blue light. For example, the light emitting layer 134 may be the organic light emitting layer, an inorganic light emitting layer, a nano-sized material layer, a quantum dot layer, a micro LED light emitting layer, or a mini LED light emitting layer, but is not limited thereto.

The light emitting layer 134 may further include an electron injecting layer for injecting electrons into the light emitting layer, a hole injecting layer for injecting holes into the light emitting layer, an electron transporting layer for transporting the injected electrons to the light emitting layer, a hole transporting layer for transporting the injected holes to the light emitting layer, an electron blocking layer, and a hole blocking layer, but is not limited thereto.

The second electrode 136 is disposed on the light emitting layer 134 and may be formed of the single layer or the multi layers made of the metal or the alloy thereof. Further, the second electrode 136 may be made of the transparent metal oxide material such as ITO or IZO, but is not limited thereto.

Further, the second electrode 136 may be made of the half-transparent conductive material that transmits light. For example, the second electrode 136 may be made of at least one or more of the alloys such as LiF/Al, CsF/Al, Mg:Ag, Ca/Ag, Ca:Ag, LiF/Mg:Ag, LiF/Ca/Ag, or LiF/Ca:Ag.

The light emitting device D may be formed in a tandem structure. The tandem structure may include a plurality of organic light emitting layers and a charge generating layer disposed between the organic light emitting layers. The charge generating layer is disposed to adjust the charge balance between the plurality of organic light emitting layers, and may be formed of a plurality of layers including a first charge generating layer and a second charge generating layer. The charge generating layer may include an N-type charge generating layer and a P-type charge generating layer. In this case, the charge generating layer may be formed of the organic layer doped with an alkali metal such as Li, Na, K, or Cs or an alkaline earth metal such as Mg, Sr, Ba, or Ra, but is not limited thereto.

A shielding electrode 164 is formed on the fence F. The shielding electrode 164 is formed to surround the sub-pixel. The shielding electrode 164 is electrically connected to the reflective layer 160 through a second contact hole H2 formed in the fence F and the planarization layer 150. Although not shown in the drawing, the reflective layer 160 may be connected to an external power supply to apply the low potential voltage VSS, and as a result, the low potential voltage VSS may be supplied to the shielding electrode 164.

An encapsulation layer 180 is formed over the light emitting device D NA to encapsulate the light emitting device D. When the light emitting device D is exposed to impurities such as moisture or oxygen, a pixel shrinkage phenomenon in which the light emitting area is reduced or the defect such as a dark spot in the light emitting area may occur. Further, moisture or oxygen penetrating the light emitting device D oxidizes the metal electrode. The encapsulation layer 180 blocks impurities such as oxygen and moisture from the outside to prevent defects of the light emitting device D and various electrodes.

The encapsulation layer 180 may be formed of a first encapsulation layer 182a, second encapsulation layer 184, and a third encapsulation layer 186, but is not limited thereto. The encapsulation layer 180 may be formed of two layers or four or more layers.

The first encapsulation layer 182 and the third encapsulation layer 186 may be made of the inorganic material such as SiOx or SiNx, but are not limited thereto. The second encapsulation layer 184 may be made of the organic insulating material such as epoxy resin.

As described above, in the present disclosure, the shielding electrode 164 may be disposed on the fence F, and the shielding electrode 164 may be made of the same material as the first electrode 132 of the light emitting device D. This will be described in more detail.

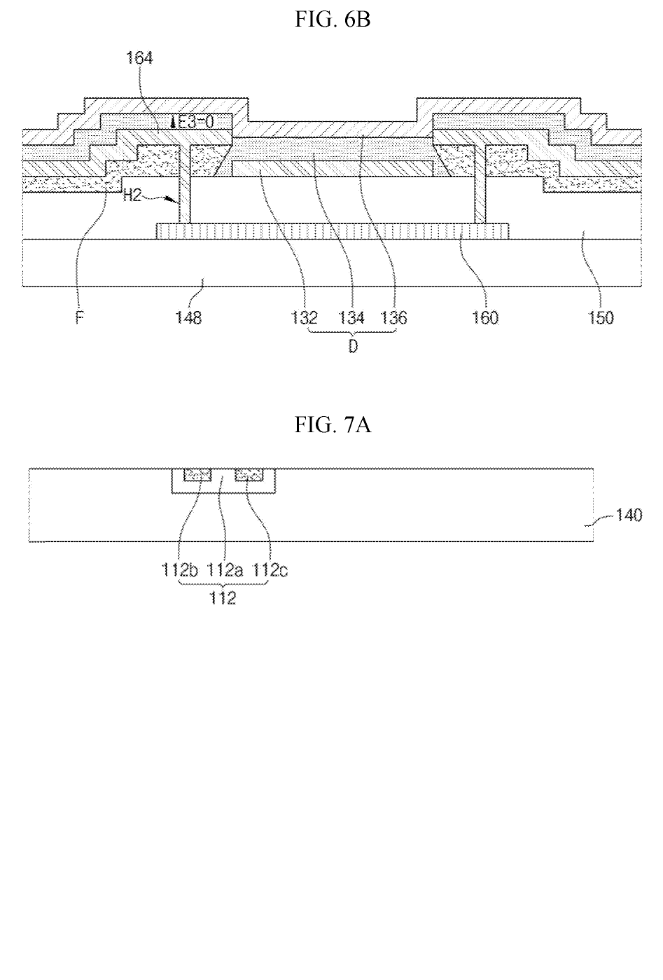

FIG. 5 is the enlarged cross-sectional view of the region A of FIG. 4. As shown in FIG. 5, the reflective layer 160 is formed on the passivation layer 148, and the planarization layer 150 is formed on the reflective layer 160. The fence F is disposed on the planarization layer 150. The fence F is formed in a boundary region of the sub-pixel to define a plurality of sub-pixels.

The end of the fence F may have an undercut shape UCUT or an overhang shape. The shielding electrode 164 is formed on the planarization layer 150 of the sub-pixel between the fences F and on the fence F between the sub-pixels.

As will be described later, the shielding electrode 164 and the first electrode 132 of the light emitting device D are integrally formed by the same process, but are electrically disconnected from each other by the undercut shape UCUT of the end of the fence F.

Further, the light emitting layer 134 is disposed on the shielding electrode 164 and the first electrode 132. In this case, the light emitting layer 134 is integrally formed, but the light emitting layer 134 on the shielding electrode 164 and the first electrode 132 is disconnected from each other by the undercut shape UCUT of the end portion of the fence F. As the light emitting layer 134 is disconnected, a lateral leakage current does not flow through the light emitting layer 134 between adjacent sub-pixels. Therefore, it is possible to prevent defects such as crosstalk caused by the side leakage current, line mura and edge mura in which colors of lines or some areas appear differently, increasing of power consumption due to unnecessary current consumption, deterioration of organic matter due to continuous leakage current, and afterimage defects.

In the present disclosure, the shielding electrode 164 is formed on the fence F to supply the low potential voltage VSS to the shielding electrode 164 through the reflective layer 160, for the following reasons.

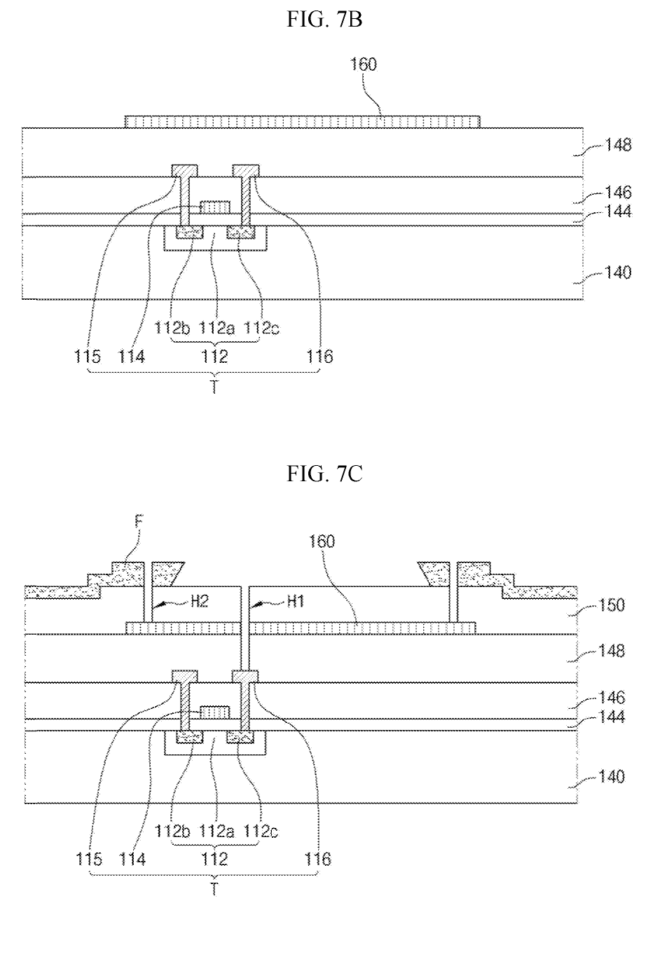

As shown in FIG. 6A, in the case of the display apparatus in which the shielding electrode is not disposed, the high potential voltage VDD is applied to the first electrode 132 and the low potential voltage VSS is applied to the second electrode 136. Thus, an electric field E1 corresponding to the voltage difference VDD-VSS is generated between the first electrode 132 and the second electrode 136.

The light emitting layer 134 emits light by the electric field E1 and then light is output to the outside. When the light emitting layer 134 of the boundary region of the sub-pixel emits light, lights of the specific colors from the adjacent sub-pixels are mixed and then output to the outside. In order to prevent the color mixing, the fence F is formed in the boundary region of each sub-pixel. The fence F is disposed between the first electrode 132 and the second electrode 136 to block the electric field E1 formed between the first electrode 132 and the second electrode 136 so that the light emitting layer 134 does not emit light in this region.

Meanwhile, recently, in order to manufacture the high-resolution display apparatus, the display apparatus 100 that minimizes the interval between sub-pixels has been manufactured. However, in this case, as the distance between the adjacent sub-pixels decreases, the side leakage current flows between the adjacent sub-pixels. Since the side leakage current mainly flows to adjacent sub-pixels through the light emitting layer 134, the electric field E2 is generated in the light emitting layer 134 of the region where the fence F is formed by the side leakage current.

The intensity of the electric field E1 of the region in which the fence F is formed may be less than that of the electric field E1 of another region (E1>E2). However, since the light emitting layer 134 emits light even by the small intensity electric field E2, the light is output to the outside even in the region in which the fence F is formed, and thus the lights of different colors from adjacent sub-pixels is mixed, so that the image quality is deteriorated.

As shown in FIG. 6B, in the display apparatus 100 according to the present disclosure, the shielding electrode 164 is formed on the fence F. The voltage may be applied to the shielding electrode 164 to increase the effect of shielding the electric field. The low potential voltage, VSS which is applied to the second electrode 136, may be supplied to the shielding electrode 164. For example, when an anode voltage of about 8V is applied to the first electrode 132 and a cathode voltage of about 0V is applied to the second electrode 136, the electric field is not generated in the light emitting layer 134 above the fence F (E3=0), and thus the light emitting layer of this region does not emit light.

The side leakage current between adjacent sub-pixels may be blocked by the undercut shape UCUT of the fence F. However, since the light emitting layer 134 cannot be completely disconnected by the undercut shape UCUT of the fence F, the cathode voltage of about 0V is applied to the shielding electrode 164 so that the light emitting layer 134 above the fence F does not emit light.

Further, this structure is equally applied even when the organic light emitting device D is formed in the tandem structure. The tandem structure includes a plurality of light emitting layers and a charge generation layer therebetween. For example, when the anode voltage of about 8V is applied to the first electrode 132 and the cathode voltage of 0V is applied to the second electrode 136, the voltage of about 4V is generated in the charge generation layer disposed within the light emitting layer 134, so that the light emitting layer disposed above and below the charge generation layer above the fence F emits light. However, when the shielding voltage of 0V is applied to the shielding electrode 164, the voltage below the threshold voltage at which the light emitting layer emits light is applied to the charge generation layer, so that the light emitting layer of this area does not emit light.

Therefore, since the light emitting layer 134 above the shielding electrode 164 does not emit light, it is possible to prevent mixing of different colors of light output from adjacent sub-pixels.

Meanwhile, in the display apparatus 100 according to the first embodiment of the present disclosure, the thin film transistor T is formed on the wafer substrate 140 and the light emitting device D is disposed thereon, but the present disclosure is not limited to this structure. In this disclosure, a hard and transparent material such as glass or a transparent material having flexibility such as plastic is used as the substrate, and the thin film transistor may be formed by directly forming the amorphous semiconductor, the crystalline semiconductor, the an oxide semiconductor on the substrate.

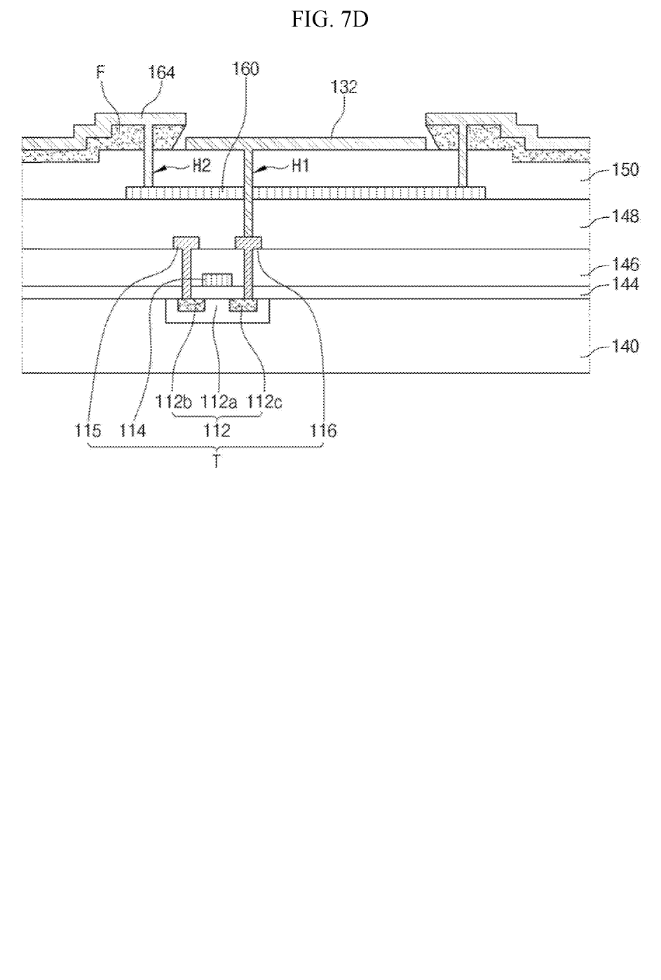

FIGS. 7A to 7F are cross-sectional views illustrating the method of manufacturing the display apparatus 100 according to the first embodiment of the present disclosure.

First, as shown in FIG. 7A, the wafer substrate 140 is formed by growing the single crystal silicon (Si) or the polycrystalline silicon, and then impurities are doped in some areas inside the wafer substrate 140 to form the channel region 112a, the source region 112b, and the drain region 112c. In this case, the source region 112band the drain region 112c are doped with impurities, and the channel region 112a between the source region 112b and the drain region 112c is not doped with impurities.

Therefore, as shown in FIG. 7B, the single layer or the multiple layers made of the inorganic materials such as SiOx or SiNx are deposited to form the gate insulating layer 144, and then molybdenum (Mo), aluminum (Al), chromium (Cr), gold (Au), titanium (Ti), nickel (Ni), neodymium (Nd), and copper (Cu) or the alloys of thereof are deposited and etched to form the gate electrode 114. In this case, the gate electrode 114 may be formed the single layer or the multi layers.

Subsequently, the organic material such as photo acrylic or the inorganic material such as SiNx or SiOx is deposited to form the interlayer insulating layer 146 including the single layer or the multiple layers.

Subsequently, the source electrode 115 and the drain electrode 116 are formed by depositing and etching the metal such as molybdenum (Mo), aluminum (Al), chromium (Cr), gold (Au), titanium (Ti), nickel (Ni), neodymium (Nd), and copper (Cu) or the alloys thereof on the interlayer insulating layer 146.

Thereafter, the organic material such as photo-acrylic is deposited to form the passivation layer 148, and the reflective layer 160 is formed on the passivation layer 148 by depositing and etching the metal with good reflectivity such as silver (Ag) or aluminum (Al).

Subsequently, the organic material such as photo acrylic is deposited to form the planarization layer 150 on the passivation layer 148 on which the reflective layer 160 is disposed. The planarization layer 150 may be formed of the same material as the passivation layer 148 or may be formed of the different material.

Thereafter, the inorganic material such as SiOx or SiNx is deposited on the planarization layer 150 and etched to form the fence F in the boundary region of the sub-pixel on the planarization layer 150. In this case, a portion of the inorganic material is removed to expose the planarization layer 150 to the outside in the area between the fences F, and the fence F is over-etched to form the undercut shape or the overhang shape.

In this case, the second contact hole H2 is formed in the passivation layer 148 and the planarization layer 150 above the reflective layer 160. The second contact hole H2 may be formed by separately etching the passivation layer 148 and the planarization layer 150, or may be formed by simultaneously etching the passivation layer 148 and the planarization layer 150.

Therefore, as shown in FIG. 7D, at least one of the half-transparent alloys such as LiF/Al, CsF/Al, Mg:Ag, Ca/Ag, Ca:Ag, LiF/Mg:Ag, LiF/Ca/Ag, LiF/Ca:Ag, or at least one of the transparent metal oxides such as TO and IZO are deposited over the entire substrate 140 to form the first electrode 132 on the planarization layer 150 in the exposed area between the fences F and form a shielding electrode 164 on the fence F.

At this time, since the end of the fence F is formed in the undercut or the overhang shape, the first electrode 132 and the shielding electrode 164 formed in the same depositing process are disconnected from each other in the undercut or the overhang shape.

In other words, in the display apparatus 100 according to the present disclosure, the metal is simply deposited to form the first electrode 132 and the shielding electrode 164 disconnected from each other without a separate masking process, so that the mask process for forming the first electrode 132 and the mask process for forming the shielding electrode 164 can be omitted.

Afterwards, as shown in FIG. 7E, the light emitting layer 134 is deposited over the entire substrate 140. In this case, the light emitting layer 134 may also be disconnected between adjacent sub-pixels due to the undercut shape of the end portion of the fence F.

Thereafter, as shown in FIG. 7F, the second electrode 136 is formed by depositing the metal oxide such as ITO or IZO on the light emitting layer 134. In this case, the undercut shape of the end of the fence F is alleviated by the first electrode 132 and the light emitting layer 134, so that the second electrode 136 may be integrally formed over the entire substrate 140 without disconnection.

Subsequently, the encapsulation layer 180 including the first encapsulation layer 182, the second encapsulation layer 184, and the third encapsulation layer 186 is formed over the light emitting device D. In this case, the first encapsulation layer 182 and the third encapsulation layer 186 may be formed by depositing the inorganic materials, and the second encapsulation layer 184 may be formed by depositing the organic materials.

As described above, in the display apparatus 100 according to the present disclosure, since the first electrode 132 and the shielding electrode 164 of the light emitting device D are formed through one process, the manufacturing process may be simplified and the manufacturing cost may be reduced.

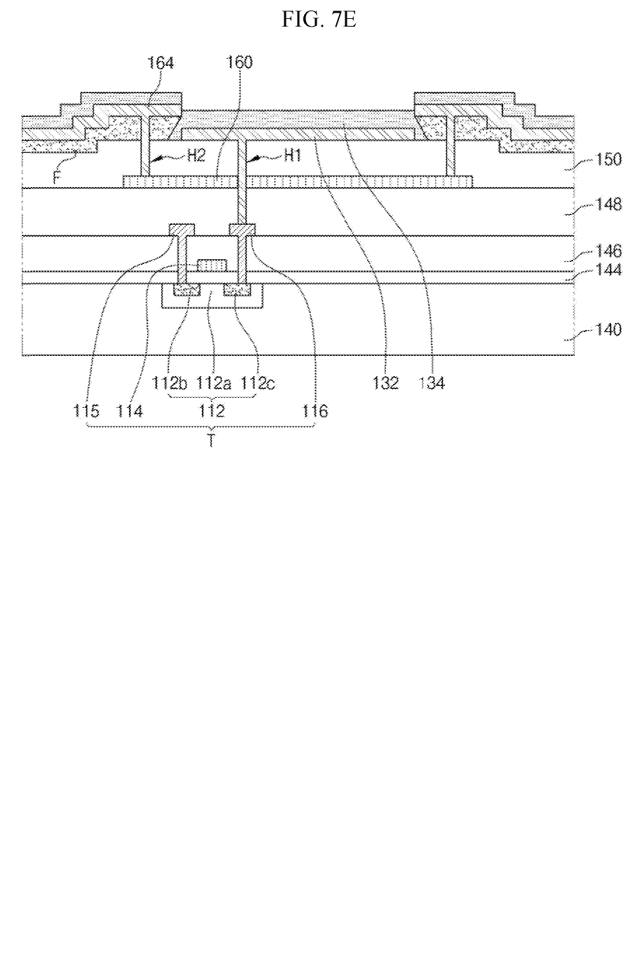

FIG. 8 is the cross-sectional view illustrating the structure of the display apparatus 200 according to a second embodiment of the present disclosure. In this case, for convenience of description, only the reflective layer 260, the upper fence F, and the light emitting device D are illustrated.

As shown in FIG. 8, the reflective layer 260 is formed on the passivation layer 248, and the planarization layer 250 is formed on the passivation layer 248.

The fence F is disposed in the area between adjacent sub-pixels on the planarization layer 250. In this case, the fence F is formed by etching the inorganic layer such as SiOx or SiNx, and the end of the fence F is formed in the undercut shape or the overhang shape by the over-etching.

Further, the groove C is formed in the planarization layer 250 corresponding to the end of the fence F. The groove C may be formed by etching a part of the planarization layer 250 corresponding to the end of the fence F after the formation of the fence F.

The fence F is formed to surround the sub-pixel, so that the planarization layer 250 within the sub-pixel is exposed to the outside through the area between the fences F. The first electrode 232 is formed on the exposed planarization layer 250 of the sub-pixel, and the shielding electrode 264 is formed on the fence F of the area between the sub-pixels.

The light emitting layer 234 is formed on the shielding electrode 264 and the first electrode 232 and the second electrode 236 is formed on the light emitting layer 234, so that and the light emitting device D is disposed in the sub-pixel.

The contact hole H2 is formed in the planarization layer 250 and the fence F, and the shielding electrode 264 is electrically connected to the reflective layer 260 through the contact hole H2. In this case, since the low potential voltage VSS applied to the second electrode 236 is supplied to the shielding electrode 264 through the reflective layer 260, the voltage of the same potential is applied to the shielding electrode 264 and the second electrode 236. Accordingly, since the electric field is not generated between the shielding electrode 264 and the second electrode 236, the light emitting layer 234 above the shielding electrode 264 does not emit light.

Therefore, even when the side leakage current is introduced from the adjacent sub-pixels, the light emitting layer 234 does not emit light at the boundary of the sub-pixels. Therefore, it is possible to more efficiently prevent the color mixing between adjacent sub-pixels.

The first electrode 232 and the shielding electrode 264 may be formed by depositing the half-transparent metal or the transparent metal and then etching the deposited metal by a single mask process. The groove C of the planarization layer 150 is aligned with the undercut shape UCUT of the fence F, so that the first electrode 232 and the shielding electrode 264 are reliably disconnected at the groove C and the undercut shape UCUT when the first electrode 232 and the shielding electrode 264 are formed. As a result, the different voltages (that is, the high potential voltage and the low potential voltage) may be applied to the first electrode 232 and the shielding electrode 264, respectively, to prevent light emission of the light emitting layer 234 between the sub-pixels.

Further, since the light emitting layer 234 is also disconnected at the groove C and the undercut shape UCUT, the side leakage current does not flow to adjacent sub-pixels through the light emitting layer 234.

The encapsulation layer 280 is formed on the light emitting device D to complete the display apparatus 200.

In the display apparatus 200 of this embodiment, since the light emitting layer 234 between the adjacent sub-pixels is disconnected by the undercut shape UCUT of the fence F and the groove C of the planarization layer 250, it is possible to minimize the flow of the side leakage current to the adjacent sub-pixels through the light emitting layer 234.

Further, in the display apparatus 200 of this embodiment, since the electric field is not generated in the area between sub-pixels, the light emitting layer does not emit light at the sub-pixel boundary even when the side leakage current flows from the adjacent sub-pixel. Therefore, it is possible to more efficiently prevent the color mixing between adjacent sub-pixels.

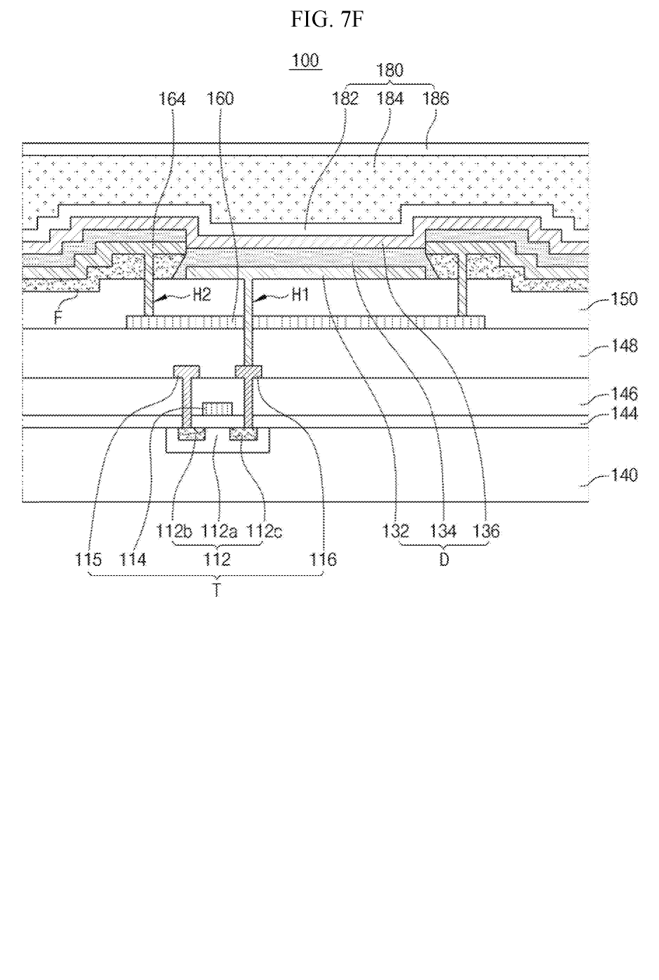

FIG. 9 is the cross-sectional view illustrating the structure of the display apparatus 300 according to a third embodiment of the present disclosure. In this case, adjacent R, G, and B sub-pixels are shown in the drawings, and particularly, for convenience of description, only the reflective layer 360 of each sub-pixel, the fence F, and the light emitting element D are shown.

As shown in FIG. 9, the display apparatus 300 of this embodiment includes a plurality of R, G, and B sub-pixels.

The first reflective layer 360R is disposed in the sub-pixel R on the passivation layer 348, and the first planarization layer 350a is formed on the passivation layer 348 on which the first reflective layer 360R is disposed. The second reflective layer 360G is disposed in the G sub-pixel on the first planarization layer 350a, and the voltage line 366 is disposed in the B sub-pixel on the first planarization layer 350a. In this case, the voltage line 366 may be formed of the same metal by the same process as that of the second reflective layer 360G, but may also be formed of different metal by different processes.

Further, the voltage line 366 may be formed on the passivation layer 348. In this case, the voltage line 366 may be made of the same metal by the same process as that of the first reflective layer 360R, but may be formed of the different metal by the different process.

The second planarization layer 350b is formed on the first planarization layer 350a on which the second reflective layer 360G is disposed. The third reflective layer 360B is disposed in sub-pixels B on the second planarization layer 350b.

The first-third reflective layers 360R, 360G, and 360B may be made of the metal having good reflectivity, such as silver (Ag) or aluminum (Al). In this case, all of the first-third reflective layers 360R, 360G, and 360B may be made of the same material or different materials.

The fence F is disposed in the region between R, G, and B sub-pixels on the second planarization layer 350band extends to a partial region of the R, G, and B sub-pixels. In this case, the end of the fence F is over-etched to form the undercut shape or the overhang structure. Since the third reflective layer 360B is disposed in sub-pixels above the second planarization layer 350b and the fence F is disposed between the sub-pixels, a part of the fence F extends on the third reflective layer 360B in the sub-pixel B so that the third reflective layer 360B is exposed to the outside through the fence F.

The first electrode 332 is disposed in sub-pixels R, G, and B between the fences F, and the shielding electrode 364 is disposed on the fence F. In this case, the first electrode 332 is disposed on the third planarization layer 350b exposed between the fences F in the R, G sub-pixels, and the first electrode 332 is disposed on the third reflective layer 360B exposed between the fences F in the B sub-pixel. That is, in the B sub-pixel, the first electrode 332 and the third reflective layer 360B are in direct contact with each other.

The shielding electrode 364 disposed in the sub-pixel R is electrically connected to the first reflective layer 360R through the first contact hole H1 formed in the first planarization layer 350a, the second planarization layer 350b, and the fence F. The shielding electrode 364 and the first electrode 324 are disconnected by the undercut shape of the end of the fence F, and the low potential voltage VSS is applied to the shielding electrode 364 through the first reflective layer 360R, and the high potential voltage is applied to the first electrode 324.

The shielding electrode 364 disposed in the G sub-pixel is electrically connected to the second reflective layer 360G through the second contact hole H2 formed in the second planarization layer 350b and the fence F, so that the low potential voltage VSS is applied to the shielding electrode 364 through the second reflective layer 360G.

The shielding electrode 364 disposed in the sub-pixel B is electrically connected to the voltage line 366 through the third contact hole H3 formed in the second planarization layer 350b and the fence F, so that the low potential voltage VSS is applied to the shielding electrode 364 through the voltage line 366. When the voltage line 366 is formed on the passivation layer 348, the shielding electrode 364 may be electrically connected to the voltage line 366 through contact holes formed in the first planarization layer 350a, the second planarization layer 350b, and the fence F.

The low potential voltage VSS is applied to the shielding electrode 364 of the R, G sub-pixels through the first reflective layer 360Rand the second reflective layer 360G, respectively. On the other hand, in the sub-pixel B, since the third reflective layer 360B is electrically connected to the first electrode 332, a low potential voltage VSS different from the high potential voltage VDD applied to the first electrode 332 is applied to the shielding electrode 364 through a separate voltage line 366.

The light emitting layer 334 is formed on the shielding electrode 364 and the first electrode 332 and the second electrode 336 is formed on the light emitting layer 334 so that the light emitting device D is disposed in each of the R, G, and B sub-pixels.

Since the low potential voltage VSS applied to the second electrode 336 is applied to the shielding electrode 364, the voltage of the same potential is applied to the shielding electrode 364 and the second electrode 336. Accordingly, since the electric field is not generated between the shielding electrode 364 and the second electrode 336, the light emitting layer 334 above the shielding electrode 364 does not emit light. Further, since the light emitting layer 334 is disconnected at the undercut shape, the side leakage current does not flow to adjacent sub-pixels through the light emitting layer 334.

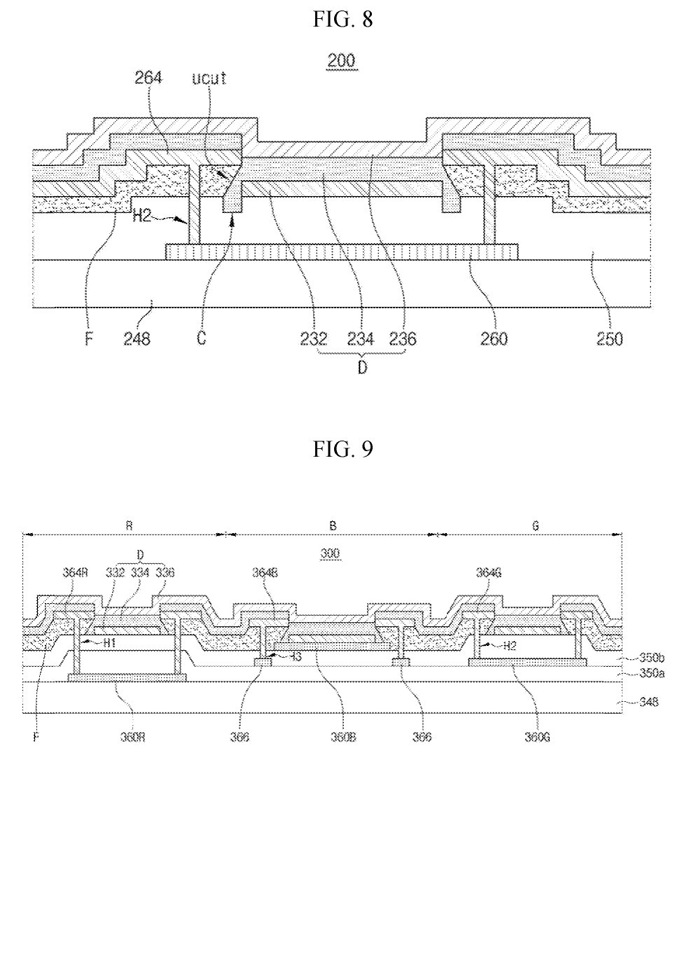

FIG. 10 is the cross-sectional view illustrating the structure of the display apparatus 400 according to a fourth embodiment of the present disclosure. In this case, adjacent R, G, and B sub-pixels are shown in the drawings, and particularly, for convenience of description, only the reflective layer 360 of each sub-pixel, the fence F, and the light emitting element D are shown.

As shown in FIG. 10, the display apparatus 400 of this embodiment includes a plurality of R, G, and B sub-pixels.

The first reflective layer 460R is disposed in the sub-pixel R on the passivation layer 448, and the first planarization layer 450a is formed on the passivation layer 448 on which the first reflective layer 460R is disposed. The second reflective layer 460Gis disposed in the G sub-pixel on the first planarization layer 450a. In this case, the first reflective layer 460Ris extended to a partial area of the B sub-pixel from the R sub-pixel, and the second reflective layer 460Gis extended to a partial area of the B sub-pixel from the G sub-pixel.

The second planarization layer 450b is formed on the first planarization layer 450a on which the second reflective layer 460G is disposed. The third reflective layer 460B is disposed in sub-pixels B on the second planarization layer 450b.

The first-third reflective layers 460R, 460G, and 460B may be made of the metal having good reflectivity, such as silver (Ag) or aluminum (Al). In this case, all of the first-third reflective layers 460R, 460G, and 460B may be made of the same material or different materials.

The fence F is disposed in the region between R, G, and B sub-pixels on the second planarization layer 450b and extends to a partial region of the R, G, and B sub-pixels. In this case, the end of the fence F is over-etched to form the undercut shape or the overhang structure. Since the third reflective layer 460B is disposed in sub-pixels above the second planarization layer 450b and the fence F is disposed between the sub-pixels, a part of the fence F extends on the third reflective layer 460B in the sub-pixel B so that the third reflective layer 460B is exposed to the outside through the fence F.

The first electrode 432 is disposed in sub-pixels R, G, and B between the fences F, and the shielding electrode 464 is disposed on the fence F. In this case, the first electrode 432 is disposed on the second planarization layer 450b exposed between the fences F in the R, G sub-pixels, and the first electrode 432 is disposed on the third reflective layer 460B exposed between the fences F in the B sub-pixel. That is, in the B sub-pixel, the first electrode 432 and the third reflective layer 460B are in direct contact with each other.

The shielding electrode 464 disposed in the sub-pixel R is electrically connected to the first reflective layer 460R through the first contact hole H1 formed in the first planarization layer 450a, the second planarization layer 450b, and the fence F. The shielding electrode 464 and the first electrode 432 are disconnected by the undercut shape of the end of the fence F, and the low potential voltage VSS is applied to the shielding electrode 464 through the first reflective layer 460R, and the high potential voltage is applied to the first electrode 432.

The shielding electrode 464 disposed in the G sub-pixel is electrically connected to the second reflective layer 460G through the second contact hole H2 formed in the second planarization layer 450b and the fence F, so that the low potential voltage VSS is applied to the shielding electrode 464 through the second reflective layer 460G.

The shielding electrode 464 adjacent to the R sub-pixel among the shielding electrodes 464 disposed on both sides of the B sub-pixel is electrically connected to the first reflective layer 460R extending to the B sub-pixel through the third contact hole H3 formed in the first planarization layer 450a, the second planarization layer 450b, and the fence F, and thus the low potential voltage VSS is applied to the shielding electrode 464 through the first reflective layer 460R. The shielding electrode 464 adjacent to the G sub-pixel among the shielding electrodes 464 disposed on both sides of the B sub-pixel is electrically connected to the second reflective layer 460G extending to the G sub-pixel through the fourth contact hole H4 formed in the second planarization layer 450b and the fence F, and thus the low potential voltage VSS is applied to the shielding electrode 464 through the second reflective layer 460G.

The difference between the display apparatus 400 of the present embodiment and the display apparatus 300 of the third embodiment shown in FIG. 9 is as follows. In the display apparatus 300 according to the third embodiment, the voltage line 366 is disposed to apply the low potential voltage VSS to the shielding electrode 364 of the sub-pixel B. On the other hand, in the display apparatus 400 according to the present embodiment, the low potential voltage VSS is applied through the first reflective layer 460R and the second reflective layer 460G extending to the B sub-pixel. Accordingly, in the display apparatus 400 according to the present embodiment, the voltage line for applying the low potential voltage VSS is not necessary.

The light emitting layer 434 is formed on the shielding electrode 464 and the first electrode 432, and the second electrode 436 is formed on the light emitting layer 434, so that the light emitting element D is disposed on each of the R, G, and B sub-pixels.

In the display apparatus 400 according to the present embodiment, since the same low potential voltage VSS is applied to the shielding electrode 464 and the second electrode 436, the electric field is not generated between the shielding electrode 464 and the second electrode 436, and as a result, the light emitting layer 434 above the shielding electrode 464 does not emit light.

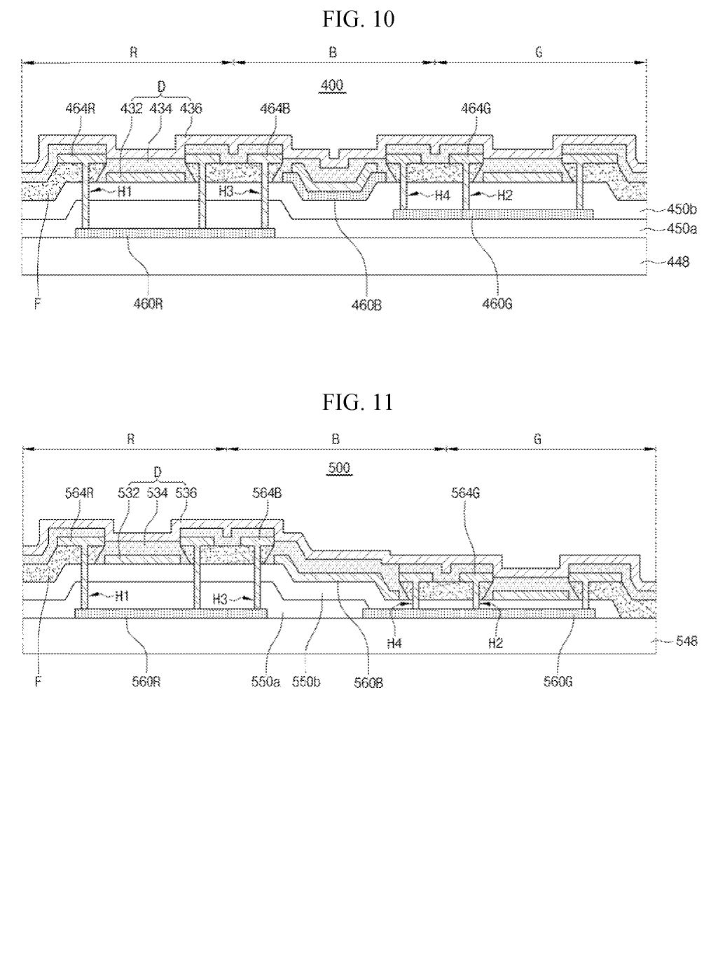

FIG. 11 is the cross-sectional view illustrating the structure of the display apparatus 500 according to a fourth embodiment of the present disclosure. In this case, adjacent R, G, and B sub-pixels are shown in the drawings, and particularly, for convenience of description, only the reflective layer 360 of each sub-pixel, the fence F, and the light emitting element D are shown.

In the display apparatus 500 of this embodiment, as shown in FIG. 11, the first reflective layer 560R is disposed in the R sub-pixel, the second reflective layer 560G is disposed in the G sub-pixel, and the third reflective layer 560B is disposed in the B sub-pixel. In this case, the first reflective layer 560R is disposed in the R sub-pixel on the passivation layer 548, the first planarization layer 550a and the second planarization layer 550b are formed on the first reflective layer 560R, and the light emitting element D is disposed on the second planarization layer 550b

The second reflective layer 560G is also disposed in the G sub-pixel on the passivation layer 548, the second planarization layer 550b is formed on the second reflective layer 560G, and the light emitting device D is disposed on the second planarization layer 550b. That is, the first planarization layer 550a is formed in the R sub-pixel but not in the G sub- pixel. Therefore, the length of micro-cavity is determined by the first planarization layer 550a and the second planarization layer 550b in the R sub-pixel where relatively long wavelength light is output, and the length of micro-cavity is determined only by the second planarization layer 550b in the G sub-pixel where relatively short wavelength light is output.

The first planarization layer 550a may be formed only in the R sub-pixel and is formed in some regions of the R sub-pixel and the B sub-pixel, but is not formed in the G sub-pixel.

The third reflective layer 560B is formed in the B sub-pixel on the second planarization layer 550b, and the light emitting element is disposed on the third reflective layer 560B. The first reflective layer 560R is extended to a partial area of the B sub-pixel from the R sub-pixel, and the second reflective layer 560G is extended to a partial area of the B sub-pixel from the G sub-pixel.

The first to third reflective layers 560R, 560G, and 560B may be made of the metal having good reflectivity, such as silver (Ag) or aluminum (Al). In this case, all of the first to third reflective layers 560R, 560G, and 560B may be formed of the same material or different materials.

The fence F is disposed in the area between R, G, and B sub-pixels on the second planarization layer 550b and extended to a partial region of the R, G, and B sub-pixels. In this case, the end of the fence F is over-etched to form the undercut shape or the overhang structure.

The shielding electrode 564 is disposed on the fence F. The shielding electrode 564 is formed simultaneously with the first electrode 532 of the light emitting device D, but the shielding electrode 564 and the first electrode 532 are separated by the undercut shape of the fence F.

The shielding electrode 564 disposed in the R sub-pixel is electrically connected to the first reflective layer 560R through the first contact hole H1 formed in the first planarization layer 550a, the second planarization layer 550b, and the fence F. The shielding electrode 564 and the first electrode 532 are disconnected by the undercut shape at the end of the fence F, and the low potential voltage is applied to the shielding electrode 564 through the first reflective layer 560R and the high potential voltage is applied to the first electrode 532.

The shielding electrode 564 disposed in the G sub-pixel is electrically connected to the second reflective layer 560G through the second contact hole H2 formed in the second planarization layer 550b and the fence F, so that the low potential voltage VSS is applied to the shielding electrode 564 through the second reflective layer 560G.

The shielding electrode 564 adjacent to the R sub-pixel among the shielding electrodes 564 disposed on both sides of the B sub-pixel is electrically connected to the first reflective layer 560R extending to the B sub-pixel through the third contact hole H3 formed in the first planarization layer 550a, the second planarization layer 550b, and the fence F, and thus the low potential voltage VSS is applied to the shielding electrode 564 through the first reflective layer 560R. The shielding electrode 564 adjacent to the G sub-pixel among the shielding electrodes 564 disposed on both sides of the B sub-pixel is electrically connected to the second reflective layer 560G extending to the G sub-pixel through the fourth contact hole H4 formed in the second planarization layer 550b and the fence F, and thus the low potential voltage VSS is applied to the shielding electrode 564 through the second reflective layer 560G.

The light emitting layer 534 is formed on the shielding electrode 564 and the first electrode 532, and the second electrode 536 is formed on the light emitting layer 534, so that the light emitting element D is disposed on each of the R, G, and B sub-pixels.

The above description and the accompanying drawings are merely illustrative of the technical spirit of the present disclosure, and those of ordinary skill in the art to which the present disclosure pertains can combine configurations within a range that does not depart from the essential characteristics of the present disclosure, various modifications or variations such as separation, substitution and alteration will be possible. Therefore, the embodiments disclosed in the present disclosure are not intended to limit the technical spirit of the present disclosure, but to explain, and the scope of the technical spirit of the present disclosure is not limited by these embodiments.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display apparatus, comprising:
a substrate including a plurality of sub-pixels;
a light emitting device disposed in each sub-pixel of the plurality of sub-pixels, the light emitting device including a first electrode, a light emitting layer, and a second electrode;
a fence disposed along an outer periphery of each sub-pixel, and an end of the fence being formed in an undercut shape; and
a shielding electrode on the fence, the shielding electrode being integrally formed with the first electrode,
wherein the first electrode and the shielding electrode are electrically disconnected by the undercut shape, and
wherein a voltage is configured to be applied to the shielding electrode.

2. The display apparatus of claim 1, wherein the shielding electrode and the second electrode have a same potential.

3. The display apparatus of claim 1, wherein the substrate comprises a wafer, a plastic material, glass, or a combination thereof.

4. The display apparatus of claim 1, further comprising:
a thin film transistor disposed in each of the sub-pixels; and
a passivation layer over the thin film transistor;
a first contact hole formed in the passivation layer,
wherein the thin film transistor is electrically connected to the first electrode through the first contact hole.

5. The display apparatus of claim 4, further comprising:
a reflective layer over the passivation layer;
a planarization layer covering the reflective layer and on which the light emitting device is disposed;
a second contact hole formed in the planarization layer; and
a third contact hole formed in the fence,
wherein the shielding electrode is electrically connected to the reflective layer through the second contact hole and the third contact hole.

6. The display apparatus of claim 5, wherein a groove is formed in the planarization layer in a region corresponding to the undercut shape of the fence.

7. The display apparatus of claim 5, wherein an external power voltage is supplied to the shielding electrode through the reflective layer.

8. The display apparatus of claim 7, wherein the power supply voltage is a low potential voltage.

9. A display apparatus, comprising:
a substrate including a plurality of R (Red), G (Green), B (Blue) sub-pixels;
a light emitting device disposed in each of the R, G, B sub-pixels, the light emitting device including a first electrode, a light emitting layer, and a second electrode;
a fence disposed along an outer periphery of each of the R, G, B sub-pixels, an end of the fence being formed in an undercut shape; and
a shielding electrode on the fence, the shielding electrode being integrally formed with the first electrode,
wherein first electrode and the shielding electrode are electrically disconnected by the undercut shape, and
wherein a voltage is configured to be applied to the shielding electrode.

10. The display apparatus of claim 9, further comprising:
a thin film transistor disposed in each of the R, G, B sub-pixels;
a passivation layer over the thin film transistor;
a first reflective layer on the passivation layer in the R sub-pixel;
a first planarization layer disposed on the passivation layer on which the first reflective layer is disposed;
a second reflective layer on the first planarization layer in the G sub-pixel;
a second planarization layer disposed on the first planarization layer on which the second reflective layer is disposed; and
a third reflective layer on the second planarization layer in the B sub-pixel.

11. The display apparatus of claim 9, further comprising:
a thin film transistor disposed in each of the R, G, B sub-pixels;
a passivation layer over the thin film transistor;
a first reflective layer on the passivation layer in the R sub-pixel;
a second reflective layer on the passivation layer in the G sub-pixel;
a first planarization layer disposed in the R sub-pixel and a portion of the G sub-pixel on the passivation layer on which the first reflective layer is disposed;
a second planarization layer disposed in the R, G, B sub-pixels to cover the first planarization layer and the second reflective layer and
a third reflective layer on the second planarization layer in the B sub-pixel.

12. The display apparatus of claim 10, wherein the light emitting devices of the R and G sub-pixels are disposed on the second planarization layer, and
wherein the light emitting device of the B sub-pixel is disposed on the third reflective layer so that the first electrode of the B sub-pixel is directly contacted with the third reflective layer.

13. The display apparatus of claim 11, wherein the light emitting devices of the R and G sub-pixels are disposed on the second planarization layer, and
wherein the light emitting device of the B sub-pixel is disposed on the third reflective layer so that the first electrode of the B sub-pixel is directly contacted with the third reflective layer.

14. The display apparatus of claim 12, wherein the shielding electrode of the R sub-pixel is electrically connected to the first reflective layer through a first contact hole formed in the first planarization layer, the second planarization layer, and the fence to apply voltage to the shielding electrode, and
wherein the shielding electrode of the G sub-pixel is electrically connected to the second reflective layer through a second contact hole formed in the second planarization layer and the fence to apply the voltage to the shielding electrode.

15. The display apparatus of claim 14, further comprising a voltage line disposed on the first planarization layer in B sub-pixel,
wherein the shielding electrode of the B sub-pixel is electrically connected to the voltage line through a third contact hole formed in the second planarization layer and the fence to apply the voltage to the shielding electrode.

16. The display apparatus of claim 14, wherein the first reflective layer and the second reflective layer are respectively extended to a partial area of the B sub-pixel so that the shielding electrode of the B sub-pixel is electrically connected to the first reflective layer and the second reflective layer to apply the voltage to the shielding electrode.

17. The display apparatus of claim 13, wherein the shielding electrode of the R sub-pixel is electrically connected to the first reflective layer through a first contact hole formed in the first planarization layer, the second planarization layer, and the fence to apply voltage to the shielding electrode, and
wherein the shielding electrode of the G sub-pixel is electrically connected to the second reflective layer through a second contact hole formed in the second planarization layer and the fence to apply the voltage to the shielding electrode.

18. The display apparatus of claim 17, further comprising a voltage line disposed on the first planarization layer in B sub-pixel,
wherein the shielding electrode of the B sub-pixel is electrically connected to the voltage line through a third contact hole formed in the second planarization layer and the fence to apply the voltage to the shielding electrode.

19. The display apparatus of claim 18, wherein the first reflective layer and the second reflective layer are respectively extended to a partial area of the B sub-pixel so that the shielding electrode of the B sub-pixel is electrically connected to the first reflective layer and the second reflective layer to apply the voltage to the shielding electrode.

20. The display apparatus of claim 9, wherein the voltage applied to the shielding electrode has the same potential as the voltage applied to the second electrode.
